(19) United States
(12) Patent Application Publication
(10) Pub. No.: US 2022/0384561 A1
(43) Pub. Date: Dec. 1, 2022

(54) RESISTANCE ELEMENT AND ELECTRONIC DEVICE

(71) Applicant: SONY SEMICONDUCTOR SOLUTIONS CORPORATION, Kanagawa (JP)

(72) Inventors: Chihiro TOMITA, Kumamoto (JP); Tomohiro HIRAI, Kumamoto (JP)

(73) Assignee: SONY SEMICONDUCTOR SOLUTIONS CORPORATION, Kanagawa (JP)

(21) Appl. No.: 17/770,363

(22) PCT Filed: Aug. 7, 2020
(86) PCT No.: PCT/JP2020/030440

§ 371 Date: Apr. 20, 2022

(30) Foreign Application Priority Data
Oct. 31, 2019 (JP) 2019-198096

(51) Int. Cl. H01L 49/02; H01L 27/06

(52) U.S. Cl. CPC H01L 28/20; H01L 27/0676

(57) ABSTRACT

A resistance element includes a resistive film, in which the resistive film is adjacent to a protrusion formed on a surface of a semiconductor substrate, the protrusion including a step traversed by the resistive film.

### CROSS REFERENCE TO RELATED APPLICATIONS

This application claims the benefit of Japanese Priority Patent Application JP 2019-198096 filed on Oct. 31, 2019, the entire contents of which are incorporated herein by reference.

### TECHNICAL FIELD

The present disclosure relates to a resistance element and an electronic device. Specifically, the present disclosure relates to a resistance element formed on a semi-conductor substrate and an electronic device including the resistance element.

### BACKGROUND ART

In the past, passive elements formed by processing a surface of a semiconductor substrate are employed. For example, a resistance element in which a polycrystalline silicon film included in a resistor is placed in a trench formed in a semiconductor substrate is employed (for example, see PTL 1). In this resistance element, an n-type first polycrystalline silicon film, a silicon oxide film, and a p-type second polycrystalline silicon film are laminated in this order inside the trench.

### CITATION LIST

### Patent Literature

PTL 1: JP 11-330375 A

### SUMMARY

### Technical Problem

The technique in the related art has a difficulty in manufacturing a resistance element with a high resistance value. Reduction of a resistor in volume is necessary to enable a high resistance value. In the structure described in the foregoing technique, a plurality of films is laminated inside the trench formed in the semiconductor substrate. Accordingly, there is a limit in reducing the volume of the resistor, which makes it difficult to manufacture a resistance element with a high resistance value. On the other hand, in a case where a resistor with a long resistance pattern is formed to yield a resistance element with a high resistance value, there is a problem that an area occupied by the resistance element increases.

### Solution to Problem

The present disclosure has been made to solve the problems. According to a first aspect of the present disclosure, there is provided a resistance element including a resistive film, in which the resistive film is adjacent to a protrusion formed on a surface of a semiconductor substrate, the protrusion including a step traversed by the resistive film.

In addition, in the first aspect, the resistance element may include a plurality of the resistive films connected in series.

Furthermore, in the first aspect, the plurality of the resistive films traversing the step of each of a plurality of the protrusions on the semiconductor substrate may be connected in series.

Still further, in the first aspect, the resistance element may further include a protective film placed between the plurality of resistive films connected in series between the plurality of protrusions.

Still further, in the first aspect, two adjacent protrusions of the plurality of protrusions may be placed at an interval exceeding twice a thickness of the resistive film.

Still further, in the first aspect, the resistive film may be adjacent to the protrusion via an insulating film.

Still further, in the first aspect, the resistance element may further include an insulating layer placed on the surface of the semiconductor substrate adjacent to the protrusion, in which the resistive film traverses a step between the insulating layer and the protrusion.

Still further, in the first aspect, the protrusion may have a height of about 400 nm or less from the insulating layer.

Still further, in the first aspect, the resistive film may include polycrystalline silicon.

Still further, in the first aspect, the protrusion may be formed by grinding a surface of the semiconductor substrate around the protrusion.

Still further, in the first aspect, the protrusion may be formed simultaneously with a fin of a fin transistor placed on the semiconductor substrate.

In addition, according to a second aspect of the present disclosure, there is provided an electronic device including: a resistance element including a resistive film adjacent to a protrusion formed on a surface of a semiconductor substrate, the protrusion including a step traversed by the resistive film; and a transistor placed on the semiconductor substrate and connected to the resistance element.

According to the above aspects, a resistive film is adjacent to a side surface of a protrusion. Such a configuration makes it possible to elongate the resistive film.

### BRIEF DESCRIPTION OF DRAWINGS

FIG. 1 is a view of a configuration example of a resistance element according to a first embodiment of the present disclosure.

FIG. 2 is a cross-sectional view of the configuration example of the resistance element according to the first embodiment of the present disclosure.

FIG. 3A shows an example of a method for manufacturing the resistance element according to the first embodiment of the present disclosure.

FIG. 3B shows an example of a method for manufacturing the resistance element according to the first embodiment of the present disclosure.

FIG. 3C shows an example of a method for manufacturing the resistance element according to the first embodiment of the present disclosure.

FIG. 4D shows the example of the method for manufacturing the resistance element according to the first embodiment of the present disclosure.

FIG. 4E shows the example of the method for manufacturing the resistance element according to the first embodiment of the present disclosure.

FIG. 4F shows the example of the method for manufacturing the resistance element according to the first embodiment of the present disclosure.

FIG. 4G shows the example of the method for manufacturing the resistance element according to the first embodiment of the present disclosure.

FIG. 5H shows the example of the method for manufacturing the resistance element according to the first embodiment of the present disclosure.

FIG. 5I shows the example of the method for manufacturing the resistance element according to the first embodiment of the present disclosure.

FIG. 5J shows the example of the method for manufacturing the resistance element according to the first embodiment of the present disclosure.

FIG. 6K shows the example of the method for manufacturing the resistance element according to the first embodiment of the present disclosure.

FIG. 6L shows the example of the method for manufacturing the resistance element according to the first embodiment of the present disclosure.

FIG. 6M shows the example of the method for manufacturing the resistance element according to the first embodiment of the present disclosure.

FIG. 7A is a view of other configuration example of the resistance element according to the first embodiment of the present disclosure.

FIG. 7B is a view of other configuration example of the resistance element according to the first embodiment of the present disclosure.

FIG. 7C is a view of other configuration example of the resistance element according to the first embodiment of the present disclosure.

FIG. 8 is a cross-sectional view of a configuration example of a resistance element according to a second embodiment of the present disclosure.

FIG. 9 is a cross-sectional view of a configuration example of a resistance element according to a third embodiment of the present disclosure.

FIG. 10 is a cross-sectional view of a configuration example of a resistance element according to a fourth embodiment of the present disclosure.

FIG. 11 is a view of a configuration example of an electronic device according to a fifth embodiment of the present disclosure.

FIG. 12 is a perspective view of the configuration example of the electronic device according to the fifth embodiment of the present disclosure.

FIG. 13 is a perspective view of another configuration example of the electronic device according to the fifth embodiment of the present disclosure.

### DESCRIPTION OF EMBODIMENTS

Next, an embodiment for implementing the present disclosure (hereinafter, referred to as “embodiment”) will be described with reference to the drawings. In the drawings, the same or similar parts are denoted by the same or similar reference numerals. Furthermore, an embodiment will be described in the following order.

1. First embodiment

2. Second embodiment

3. Third embodiment

4. Fourth embodiment

5. Fifth embodiment

### 1. First Embodiment

(Configuration of Resistance Element)

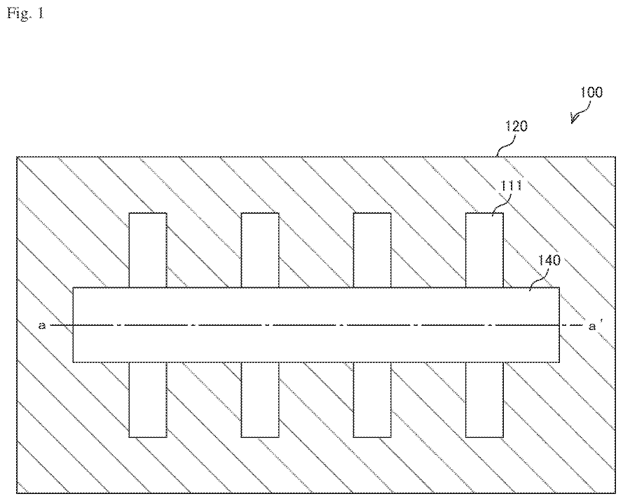

FIG. 1 is a view of a configuration example of a resistance element according to a first embodiment of the present disclosure. FIG. 1 is a plan view of a configuration example of a resistance element 100. The resistance element 100 is formed on a semiconductor substrate 110 (not shown) that has a surface provided with an insulating layer 120. The semiconductor substrate 110 includes protrusions 111, and a resistive film 140 is adjacent to the protrusions 111. In the example shown in FIG. 1, the resistance element 100 is provided with four protrusions 111 traversed by the resistive film 140.

(Cross-Sectional Configuration of Resistance Element)

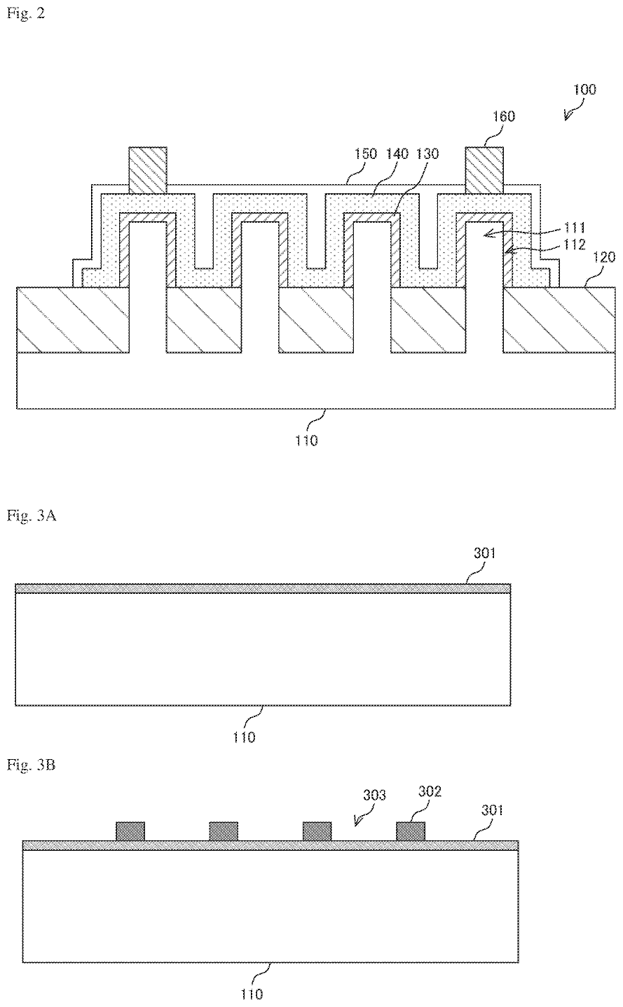

FIG. 2 is a cross-sectional view of the configuration example of the resistance element according to the first embodiment of the present disclosure. FIG. 2 is a cross-sectional view of the configuration example of the resistance element 100 taken along line a-a′ in FIG. 1. The resistance element 100 shown in FIG. 2 is formed on the surface of the semiconductor substrate 110, including the resistive film 140, an insulating film 130, a protective film 150, an insulating layer 120, and a contact plug 160.

The semiconductor substrate 110 is provided with the resistance element 100. The semiconductor substrate 110 includes, for example, silicon (Si). The semiconductor substrate 110 has n-type or p-type conductivity. Furthermore, the semiconductor substrate 110 may include a well region with a low impurity concentration. Still further, the semiconductor substrate 110 may include an intrinsic semiconductor.

The resistive film 140 is a film-shaped resistor including a resistive material having predetermined resistivity. The resistive film 140 is adjacent to the protrusions 111 which are to be described. Each protrusion 111 has a step 112 traversed by the resistive film 140. The semiconductor substrate 110 in FIG. 2 is provided with a plurality of protrusions 111 having the steps 112 traversed by the resistive film 140. The resistive film 140 traversing the steps 112 increases an effective length of the resistive film 140 and increases a resistance of the resistive film 140. The resistive film 140 includes, for example, polycrystalline silicon and the like. When polycrystalline silicon is used in the resistive film 140, it is possible to adjust the resistivity by implantation of impurities such as boron (B) and phosphorus (P). Furthermore, a metal such as tantalum (Ta) and a compound such as titanium nitride (TiN) are also employable as the resistive film 140.

Four protrusions 111 are shown in FIG. 2, but note that the number of protrusions 111 is not limited. The resistive film 140 in FIG. 2 is an example in which the resistive film placed on each of a plurality of steps 112 is connected in series.

The protrusions 111 are regions having a protruding shape formed on the surface of the semiconductor substrate 110. Each protrusion 111 includes the same member as the semiconductor substrate 110. Each protrusion 111 is formed, for example, by grinding the surface of the semiconductor substrate 110 around a region where the protrusion 111 is to be placed.

The insulating layer 120 is placed on the surface of the semiconductor substrate 110. This insulating layer 120 is placed on the surface of the semiconductor substrate 110 excluding the protrusions 111. The protrusions 111 protrude from the insulating layer 120. The insulating layer 120 may include an insulator such as silicon oxide (SiO₂) and silicon nitride (SiN). The insulating layer 120 separates the resistive film 140 from the surface of the semiconductor substrate 110 excluding the protrusions 111, which leads to reduction in parasitic capacitance of the resistance element 100.

The insulating film 130 is placed on a surface of each protrusion 111. This insulating film 130 insulates the semiconductor substrate 110 including the protrusions 111 from the resistive film 140. The insulating film 130 includes, for example, SiO₂.

The protective film 150 is a film that covers the resistive film 140 and protects the resistive film 140. This protective film 150 includes, for example, an insulator such as SiN. The protective film 150 fills a gap caused in the resistive film 140 between the adjacent protrusions 111, leading to prevention of voids.

The contact plug 160 is adjacent to the resistive film 140 and connects the resistance element 100 and a wire. This contact plug 160 includes, for example, a metal such as tungsten (W) or copper (Cu). In the example shown in FIG. 2, the contact plug 160 is placed on a surface of the resistive film 140 adjacent to the top of the protrusions 111. The contact plug 160 may also be placed on a surface of the resistive film 140 adjacent to the insulating layer 120.

The protrusions 111 are formed on the surface of the semiconductor substrate 110, and the resistive film 140 is formed to be adjacent to the protrusions 111 and across the steps 112 of the protrusions 111. Accordingly, the resistive film 140 is formed on side surfaces of the protrusions 111. Such a configuration increases an effective length of the resistive film 140 and increases a resistance of the resistive film 140. Such a configuration reduces an area occupied by the resistance element 100 on the surface of the semiconductor substrate 110.

(Method for Manufacturing Resistance Element)

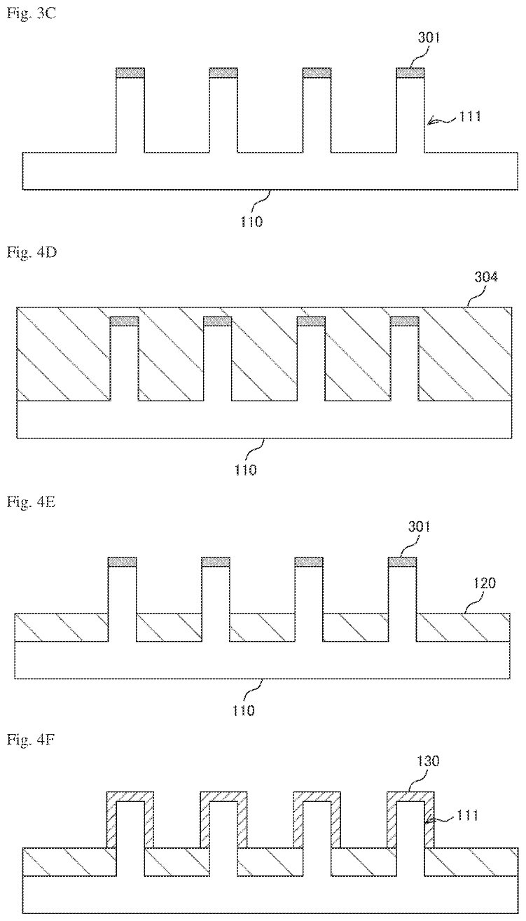

FIGS. 3A to 6M show an example of a method for manufacturing the resistance element according to the first embodiment of the present disclosure. FIGS. 3A to 6M show an example of a process for manufacturing the resistance element 100. First, the surface of the semiconductor substrate 110 is subjected to thermal oxidation to form a SiO₂ film (not shown). Next, a SiN film 301 is formed. The film formation is performed, for example, by chemical vapor deposition (CVD) (see FIG. 3A).

Next, a resist 302 is placed on a surface of the SiN film 301. An opening 303 is formed in a region of the resist 302 excluding a region where the protrusions 111 are to be formed (see FIG. 3B).

Next, the surfaces of the SiN film 301 and the semiconductor substrate 110 are ground using the resist 302 as a mask. The grinding is performed, for example, by anisotropic etching in which dry etching is employed. Due to this etching, the protrusions 111 are formed on the surface of the semiconductor substrate 110 (see FIG. 3C).

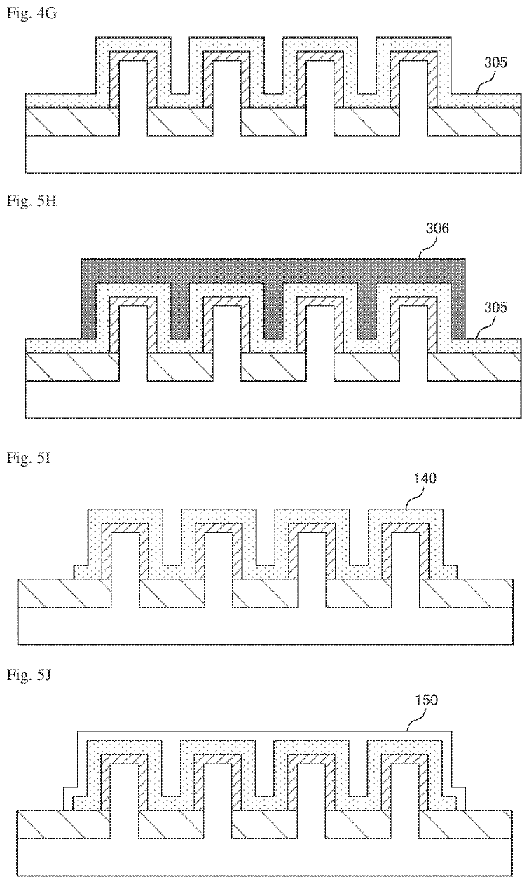

Next, a SiO₂ film 304 is placed on the surface of the semiconductor substrate 110. The film formation is performed, for example, by CVD (see FIG. 4D).

Next, the SiO₂ film 304 is ground. The grinding is performed, for example, by anisotropic etching in which dry etching is employed. Here, using the SiN film 301 as an etching stopper makes it possible to grind the SiO₂ film 304 while leaving the protrusions 111 untouched. Accordingly, the insulating layer 120 is formed (see FIG. 4E).

Next, the SiN film 301 is removed by wet etching and the like, and the insulating film 130 is placed on the surfaces of the protrusions 111 protruding from the insulating layer 120. This step is performed, for example, by thermally oxidizing the semiconductor substrate 110 including the protrusions 111 (see FIG. 4F).

Next, a resistive material film 305, which is a material of the resistive film 140, is placed. This step is performed, for example, by forming a polycrystalline silicon film by CVD (see FIG. 4G). Note that, when a resistance value of the resistive film 140 is adjusted, impurities are implanted into the resistive material film 305. The implantation is performed by ion implantation using P, B and the like as impurities, for example.

Next, on a surface of the resistive material film 305, a resist 306 having a shape of the resistive film 140 is placed (see FIG. 5H).

Next, the resistive material film 305 is etched using the resist 306 as a mask. The etching is performed, for example, by dry etching. Accordingly, the resistive film 140 is formed (see FIG. 5I).

Next, the protective film 150 is placed. This step is performed, for example, by placing a film of an insulator such as SiN or SiO₂ and etching the resistive film 140 (see FIG. 5J).

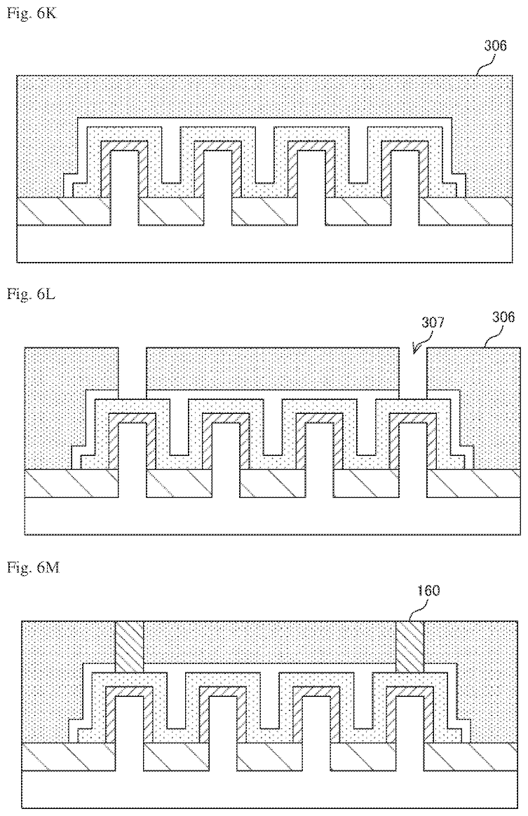

Next, an interlayer film 306 (not shown in FIG. 2) is placed. This step is performed, for example, by forming a film of an insulator such as SiO₂ by CVD and the like (see FIG. 6K).

Next, a contact hole 307 is formed in a region of the interlayer film 306 where the contact plug 160 is to be placed. This step is performed by dry etching (see FIG. 6L). Note that a silicide film may be placed on a surface of the resistive film 140 where the contact plug 160 is to be placed.

Next, a metal serving as a material of the contact plug 160, for example, W is placed in the contact hole 307 to form the contact plug 160. This step is performed, for example, by forming a W film by CVD and removing W in portions other than the contact hole 307 (see FIG. 6M). In this manner, it is possible to manufacture the resistance element 100.

(Modification)

The resistance element 100 is provided with the protrusions 111 having a rectangular cross section. However, the protrusions 111 may have a different shape.

(Other Configurations of Resistance Element)

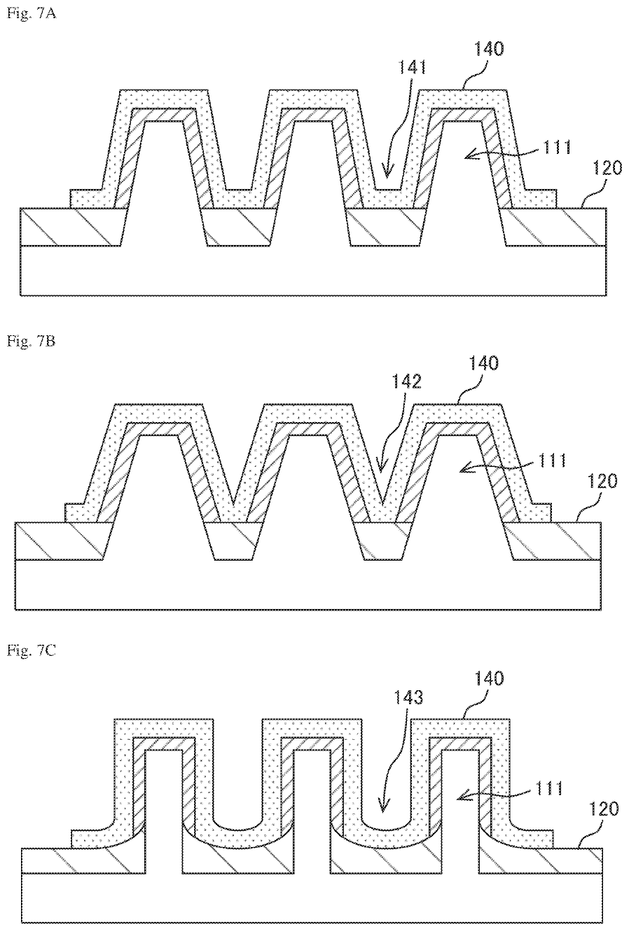

FIGS. 7A to 7C are views of other configuration examples of the resistance element according to the first embodiment of the present disclosure. In the example shown in FIG. 7A, each protrusion 111 has a tapered cross section. A resistive film 140 in FIG. 7A includes a trapezoidal cross-sectional valley 141 placed between adjacent protrusions 111.

A resistive film 140 shown in FIG. 7B is provided with protrusions 111 that has a tapered cross section, as similar to FIG. 7A, and with valleys 142 having a triangular cross section.

A resistive film 140 shown in FIG. 7C is an example, being adjacent to an insulating layer 120 having a curved surface. The resistive film 140 in FIG. 7C includes valleys 143 having a cross section curved according to the shape of a surface of the insulating layer 120.

Note that the configuration of the resistance element 100 is not limited to these examples. For example, the resistive film 140 may be placed on a protrusion 111 having a triangular or hemispherical cross section.

As described above, in the resistance element 100 according to the first embodiment of the present disclosure, the resistive film 140 is formed across the steps of the plurality of protrusions 111, which makes it possible to extend the resistive film 140 along the steps. Such a configuration increases a length of the resistive film 140 without increasing the size in the longitudinal direction. Such a configuration enables the resistive film 140 with a high resistance value and facilitates an increase in resistance of the resistance element 100.

### 2. Second Embodiment

In the resistance element 100 according to the first embodiment, the plurality of protrusions 111 is placed on the semiconductor substrate 110. In a second embodiment of the present disclosure, the size and the like of a protrusion 111 will be proposed.

(Cross-Sectional Configuration of Resistance Element)

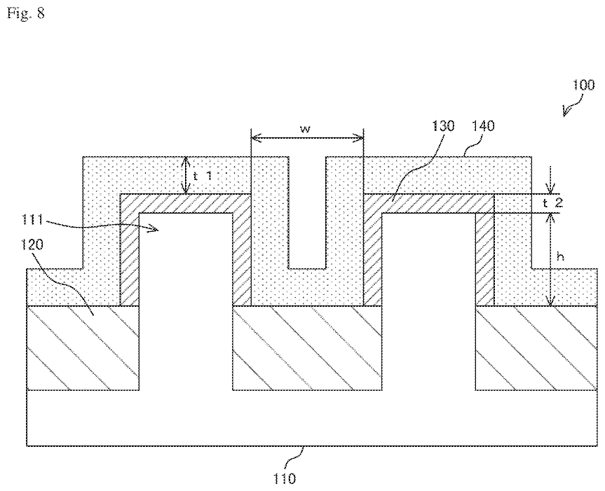

FIG. 8 is a cross-sectional view of a configuration example of a resistance element according to the second embodiment of the present disclosure. FIG. 8 simply shows a configuration example of a resistance element 100. In FIGS. 8, t1 and t2 represent a thickness of a resistive film 140 and a thickness of an insulating film 130, respectively. Furthermore, w represents an interval between adjacent protrusions 111. In a case where the insulating film 130 is placed as shown in FIG. 8, w represents an interval between insulating films 130 on surfaces of the protrusions 111. In addition, h represents a height of each protrusion 111 from a surface of an insulating layer 120.

The interval w between the protrusions 111 is preferably larger than twice the thickness t1 of the resistive film 140. This is because such a configuration prevents the resistive film 140 on a side surface of a protrusion 111 between adjacent protrusions 111 from touching the resistive film 140 on the opposite side surface and prevents a decrease in resistance value.

Furthermore, the height h of the protrusion 111 from the surface of the insulating layer 120 is preferably about 400 nm or less. As described in FIGS. 5H to 5J, the resistive film 140 is formed by dry etching the resistive material film 305 such as polycrystalline silicon adjacent to the insulating film 130 on the surfaces of the protrusions 111. In this dry etching, the top (upper surface) of each protrusion 111 is more likely to be overetched than a portion near the bottom, which easily causes damages to the insulating film 130 adjacent to the upper surface of each protrusion 111. In a case where the thickness t2 of the insulating film 130 is 10 nm, the height h is adjusted to about 400 nm or less so as to reduce damages to the insulating film 130 during the dry etching.

Other configurations of the resistance element 100 are similar to those of the resistance element 100 according to the first embodiment of the present disclosure and will not be hereinafter described.

As described above, the resistance element 100 according to the second embodiment of the present disclosure prevents a change in resistance value by defining the size of the protrusions 111 and the like.

### 3. Third Embodiment

In the resistance element 100 according to the first embodiment, the insulating layer 120 is placed on the surface of the semiconductor substrate 110. A third embodiment of the present disclosure is different from the first embodiment in that the insulating layer 120 is omitted.

(Cross-Sectional Configuration of Resistance Element)

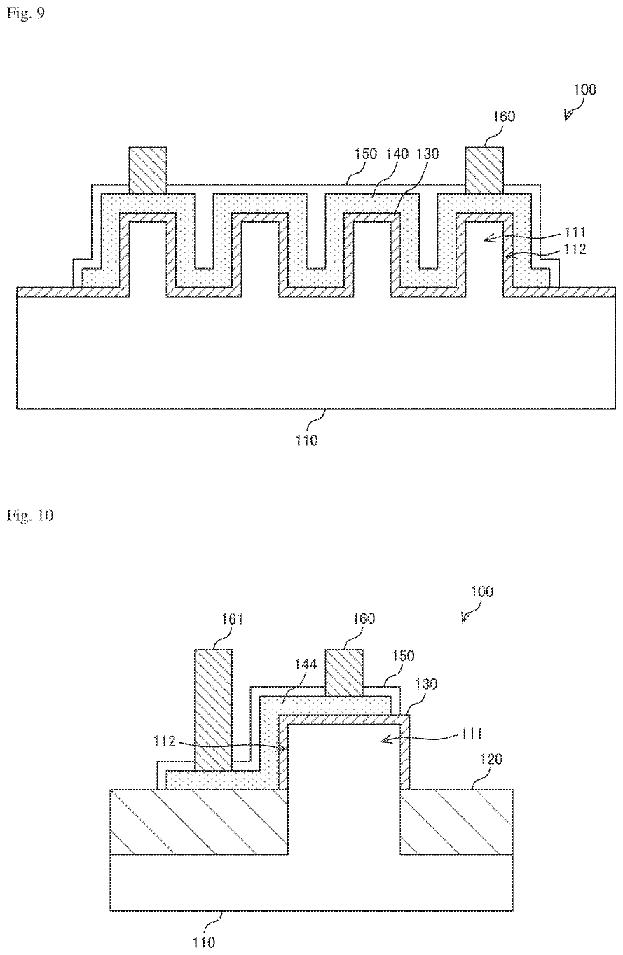

FIG. 9 is a cross-sectional view of a configuration example of a resistance element according to the third embodiment of the present disclosure. Similarly to FIG. 2, FIG. 9 shows a configuration example of a resistance element 100. FIG. 9 differs from the resistance element 100 in FIG. 2 in that the resistance element herein is provided with no insulating layer 120.

An insulating film 130 in FIG. 9 is placed on a surface of a semiconductor substrate 110 including protrusions 111 and is placed between the semiconductor substrate 110 and a resistive film 140. Accordingly, the semiconductor substrate 110 and the resistive film 140 are insulated.

Other configurations of the resistance element 100 are similar to those of the resistance element 100 according to the first embodiment of the present disclosure and will not be hereinafter described.

As described above, omission of the insulating layer 120 simplifies the configuration of the resistance element 100 according to the third embodiment of the present disclosure.

### 4. Fourth Embodiment

The resistance element 100 according to the first embodiment is provided with the plurality of protrusions 111. A fourth embodiment of the present disclosure is different from the first embodiment in that a resistance element is provided with one protrusion 111.

(Cross-Sectional Configuration of Resistance Element)

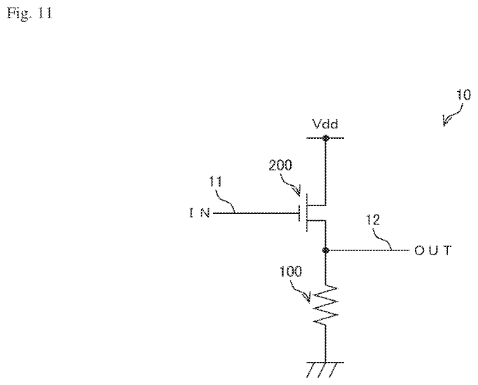

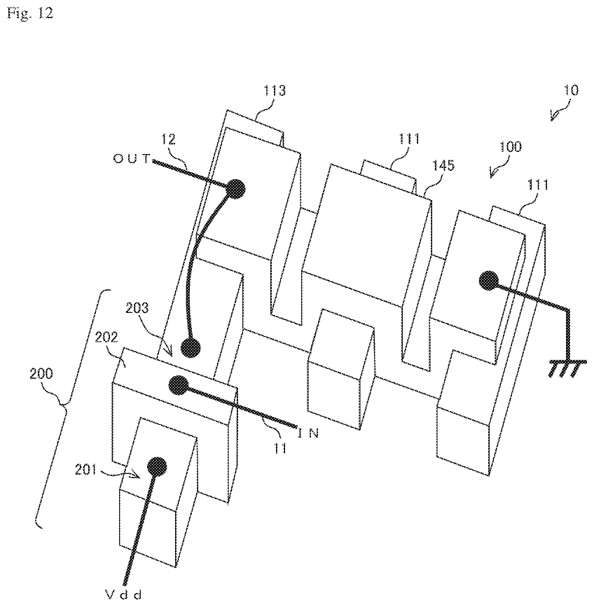

FIG. 10 is a cross-sectional view of a configuration example of a resistance element according to the fourth embodiment of the present disclosure. Similarly to FIG. 2, FIG. 10 shows a configuration example of a resistance element 100. The resistance element herein differs from the resistance element 100 in FIG. 2 in that it includes a resistive film 144 that traverses a step of one protrusion 111.

The resistive film 144 in FIG. 10 traverses only one step 112 of the protrusion 111. This resistive film 144 is provided with contact plugs 160 and 161 with different heights. The contact plug 160 is adjacent to the resistive film 144 placed on the top of the protrusion 111. On the other hand, the contact plug 161 is adjacent to the resistive film 144 which is adjacent to an insulating layer 120. Since the contact plug 161 is placed near the bottom of the step 112 of the protrusion 111, the contact plug 161 is longer than the contact plug 160.

Note that the configuration of the resistance element 100 is not limited to this example. For example, both steps 112 of the protrusion 111 may be traversed by the resistive film 144. In this case, two contact plugs 161 are placed.

Other configurations of the resistance element 100 are similar to those of the resistance element 100 according to the first embodiment of the present disclosure and will not be hereinafter described.

As described above, the resistance element 100 according to the fourth embodiment of the present disclosure includes the resistive film 144 adjacent to one protrusion 111. Accordingly, it is possible to simplify the configuration of the resistance element 100.

### 5. Fifth Embodiment

The resistance element 100 according to the first embodiment includes the resistive film 140 that traverses the protrusions 111. In a fifth embodiment of the present disclosure, described is an electronic device that includes this resistance element 100.

(Circuit Configuration of Electronic Device)

FIG. 11 is a view of a configuration example of an electronic device according to the fifth embodiment of the present disclosure. FIG. 11 is a circuit diagram showing a configuration example of an electronic device 10. The electronic device 10 in FIG. 11 includes a MOS transistor 200 and a resistance element 100. An example of the MOS transistor 200 includes an n-channel MOS transistor. The electronic device 10 in FIG. 11 corresponds to an amplifier circuit, being configured to amplify a signal input from an input signal line IN (signal line 11) and output the amplified signal to an output signal line OUT (signal line 12). Furthermore, a power wire Vdd for supplying power is wired to the electronic device 10 in FIG. 11.

The gate of the MOS transistor 200 is connected to the input signal line IN, and the drain is connected to the power wire Vdd. The source of the MOS transistor 200 is connected to one end of the resistance element 100 and to the output signal line OUT. The other end of the resistance element 100 is grounded.

The electronic device 10 in FIG. 11 is included in a source follower circuit. The resistance element 100 corresponds to the load resistance of the MOS transistor 200. As described later, a Fin transistor is employable as the MOS transistor 200. The fin transistor is a MOS transistor including a fin formed on a semiconductor substrate. Here, the fin is a fin-shaped protrusion formed on a surface of the semiconductor substrate.

(Configuration of Electronic Device)

FIG. 12 is a perspective view of the configuration example of the electronic device according to the fifth embodiment of the present disclosure. FIG. 12 is a perspective view of the configuration example of the electronic device 10, showing outer shapes and arrangements of the MOS transistor 200 and the resistance element 100 formed on a surface of a semiconductor substrate.

The resistance element 100 in FIG. 12 includes a resistive film 145. The resistive film 145 is formed to traverse steps between two protrusions 111 and a protrusion 113. The protrusion 113 is longer than the protrusions 111 and is shared with the after-mentioned fin of the MOS transistor 200. In other words, the resistance element 100 is formed at one end of the protrusion 113, and the MOS transistor 200 is formed at the other end. Note that, in the resistance element 100 in FIG. 12, an insulating film 130, an insulating layer 120, a protective film 150, a contact plug 160, and the like are omitted.

The MOS transistor 200 is a fin transistor having one end of the protrusion 113 as a fin. This MOS transistor 200 includes a drain region 201, a gate 202, and a source region 203. The drain region 201 and the source region 203 are semiconductor regions formed in the protrusion 113 and have n-type conductivity. The gate 202 crosses over the protrusion 113 between the drain region 201 and the source region 203. A channel is formed near a surface of the protrusion 113 immediately below the gate 202. Note that FIG. 12 shows an outline of the MOS transistor 200, with a gate insulating film, a sidewall, and the like omitted. Note that in the MOS transistor 200, the protrusion 113 is formed to have predetermined conductivity by ion implantation and the like after formation of the protrusion 113. As described above, the protrusion (the protrusion 113) of the resistance element 100 is shared with the fin of the MOS transistor 200 and formed simultaneously on the surface of the semiconductor substrate 110.

Note that thick lines in FIG. 12 represent wires, and closed circles represent connections between the wires and the semiconductor regions or the resistive film 145. The drain region 201 of the MOS transistor 200 is connected to the power wire Vdd, and the gate 202 is connected to the input signal line IN. The source region 203 of the MOS transistor is connected to the output signal line OUT and to one end of the resistive film 145 adjacent to the protrusion 113. The other end of the resistive film 145 is grounded.

As shown in FIG. 12, when the resistance element 100 and the MOS transistor are placed on one semiconductor substrate, it is possible to simultaneously form components such as an insulating film. For example, the insulating film 130 of the resistance element 100 may be formed simultaneously with a gate insulating film of the MOS transistor 200. Furthermore, the insulating layer 120 of the resistance element 100 may be formed simultaneously with the insulating layer provided below the gate 202 of the MOS transistor 200. Still further, the protective film 150 of the resistance element 100 may be formed simultaneously with a side wall insulating film (sidewall) of the gate 202 of the MOS transistor 200.

In this manner, since the protrusion 113 of the resistance element 100 is shared with the fin of the MOS transistor 200, it is possible to downsize the electronic device 10. Simultaneously forming the components of the resistance element 100 and the MOS transistor 200 simplifies a process for manufacturing the electronic device 10.

(Other Configurations of Electronic Device)

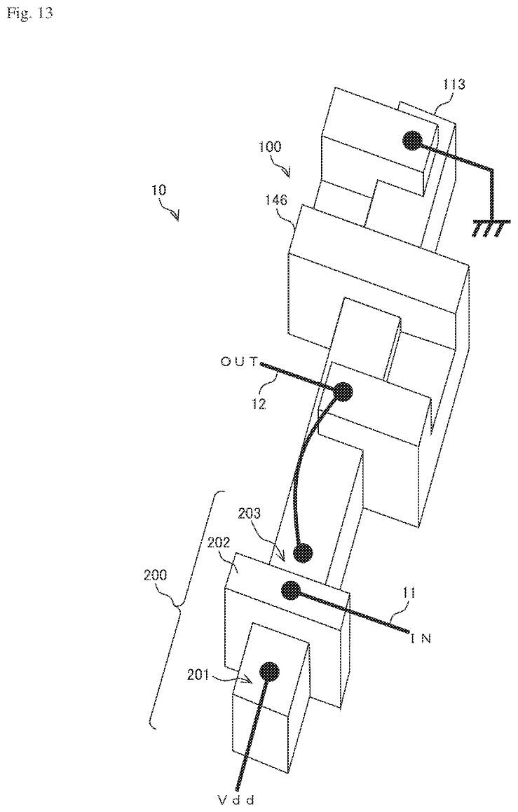

FIG. 13 is a perspective view of another configuration example of the electronic device according to the fifth embodiment of the present disclosure. Similarly to FIG. 12, FIG. 13 is a perspective view of a configuration example of the electronic device 10, showing outer shapes and arrangements of the MOS transistor 200 and the resistance element 100 formed on a surface of a semiconductor substrate. The electronic device 10 in FIG. 13 differs from the electronic device 10 in FIG. 12 in that the protrusions 111 are omitted.

The resistance element 100 in FIG. 13 includes a resistive film 146. The resistive film 146 is formed to repeatedly traverse steps of a protrusion 113. As this resistive film 146 also traverses the steps, the resistive film 146 is extended along the steps, which enables the resistive film 146 with a high resistance value.

Other configurations of the electronic device 10 are similar to those of the electronic device 10 in FIG. 12 and will not be hereinafter described.

As described above, since the electronic device 10 according to the fifth embodiment of the present disclosure uses the resistance element 100 and the MOS transistor 200 included in a fin transistor, the protrusion 111 and the like are shared. Accordingly, it is possible to downsize the resistance element 100 and to simplify a process for manufacturing the resistance element 100.

Lastly, the embodiments are examples of the present disclosure, and the present disclosure is not limited to the embodiments. Therefore, within the technical idea of the present disclosure, it is possible to employ various modifications of the embodiments according to designs and the like.

Furthermore, the effects described herein are for purposes of illustration and not limitation. The present disclosure may produce other effects.

Still further, the drawings in the embodiments are schematic views, and dimensional ratios and the like of each part do not always match actual ones. In addition, it is a matter of course that dimensional relations and ratios are different between drawings.

Note that the present technology also employs the following configurations.

(1) A resistance element including

a resistive film,

in which the resistive film is adjacent to a protrusion formed on a surface of a semiconductor substrate, the protrusion including a step traversed by the resistive film.

(2) The resistance element according to (1), further including a plurality of the resistive films connected in series.

(3) The resistance element according to (2), in which the plurality of the resistive films traversing the step of each of a plurality of the protrusions on the semiconductor substrate is connected in series.

(4) The resistance element according to (3), further including

a protective film placed between the plurality of resistive films connected in series between the plurality of protrusions.

(5) The resistance element according to (3) or (4), in which two adjacent protrusions of the plurality of protrusions are placed at an interval exceeding twice a thickness of the resistive film.

(6) The resistance element according to any one of (1) to (5), in which the resistive film is adjacent to the protrusion via an insulating film.

(7) The resistance element according to any one of (1) to (6), further including

an insulating layer placed on the surface of the semiconductor substrate adjacent to the protrusion,

in which the resistive film traverses a step between the insulating layer and the protrusion.

(8) The resistance element according to (7), in which the protrusion has a height of about 400 nm or less from the insulating layer.

(9) The resistance element according to any one of (1) to (8), in which the resistive film includes polycrystalline silicon.

(10) The resistance element according to any one of (1) to (9), in which the protrusion is formed by grinding a surface of the semiconductor substrate around the protrusion.

(11) The resistance element according to any one of (1) to (10), in which the protrusion is formed simultaneously with a fin of a fin transistor placed on the semiconductor substrate.

(12) An electronic device including:

a resistance element including a resistive film adjacent to a protrusion formed on a surface of a semiconductor substrate, the protrusion including a step traversed by the resistive film; and
a transistor placed on the semiconductor substrate and connected to the resistance element.

It should be understood by those skilled in the art that various modifications, combinations, sub-combinations and alterations may occur depending on design requirements and other factors insofar as they are within the scope of the appended claims or the equivalents thereof.

### REFERENCE SIGNS LIST

10 Electronic device

100 Resistance element

110 Semiconductor substrate

111, 113 Protrusion

112 Step

120 Insulating layer

130 Insulating film

140, 144 to 146 Resistive film

150 Protective film

160, 161 Contact plug

200 MOS transistor

What is claimed is:

1. A resistance element comprising:
a resistive film,
wherein the resistive film is adjacent to a protrusion formed on a surface of a semiconductor substrate, the protrusion including a step traversed by the resistive film.

2. The resistance element according to claim 1, further comprising:
a plurality of the resistive films connected in series.

3. The resistance element according to claim 2, wherein the plurality of the resistive films traversing the step of each of a plurality of the protrusions on the semiconductor substrate is connected in series.

4. The resistance element according to claim 3, further comprising:
a protective film placed between the plurality of resistive films connected in series between the plurality of protrusions.

5. The resistance element according to claim 3, wherein two adjacent protrusions of the plurality of protrusions are placed at an interval exceeding twice a thickness of the resistive film.

6. The resistance element according to claim 1, wherein the resistive film is adjacent to the protrusion via an insulating film.

7. The resistance element according to claim 1, further comprising:
an insulating layer placed on the surface of the semiconductor substrate adjacent to the protrusion,
wherein the resistive film traverses a step between the insulating layer and the protrusion.

8. The resistance element according to claim 7, wherein the protrusion has a height of about 400 nm or less from the insulating layer.

9. The resistance element according to claim 1, wherein the resistive film includes polycrystalline silicon.

10. The resistance element according to claim 1, wherein the protrusion is formed by grinding a surface of the semiconductor substrate around the protrusion.

11. The resistance element according to claim 1, wherein the protrusion is formed simultaneously with a fin of a fin transistor placed on the semiconductor substrate.

12. An electronic device, comprising:
a resistance element including a resistive film adjacent to a protrusion formed on a surface of a semiconductor substrate, the protrusion including a step traversed by the resistive film; and
a transistor placed on the semiconductor substrate and connected to the resistance element.
